(19) United States
(12) Patent Application Publication
(10) Pub. No.: US 2025/0160099 A1
(43) Pub. Date: May 15, 2025

(54) Light-Emitting Substrate, Backlight Module and Display Device

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Kangli Wang, Beijing (CN); Bing Zhang, Beijing (CN); Liang Gao, Beijing (CN); Yiding Sun, Beijing (CN); Ping Kang, Beijing (CN); Chenyang Wang, Beijing (CN); Xiao Wang, Beijing (CN)

(21) Appl. No.: 18/729,646

(22) PCT Filed: May 9, 2023
(86) PCT No.: PCT/CN2023/092983

§ 371 Date: Jul. 17, 2024

(30) Foreign Application Priority Data
May 16, 2022 (CN) 202210530359.4

(51) Int. Cl. H10H 29/853; G02F 1/13357; H01L 23/544; H10H 29/80

(52) U.S. Cl. CPC H10H 29/853; G02F 1/133603; G02F 1/133605; G02F 1/133608; H10H 29/8421; H01L 23/544; H01L 2223/54426

(57) ABSTRACT

A light-emitting substrate includes a first substrate, a reflective layer and support columns. The reflective layer is disposed on the first substrate and provided with first openings. At least for two of cross-sections, parallel to a place where the first substrate is located, of a first opening, an area of a cross-section relatively proximate to the first substrate is less than an area of a cross-section relatively away from the first substrate. The support columns are located on a side of the reflective layer away from the first substrate and fixed on the first substrate. An orthographic projection of a support column on the first substrate is a first projection, an orthographic projection a minimum cross-section of the cross-sections is a second projection, and the second projection lies within a range of the first projection.

This application is the United States national phase of International Application No. PCT/CN2023/092983 filed May 9. 2023. and claims priority to Chinese Patent Application No. 202210530359.4, filed May 16, 2022, the disclosures of which is hereby incorporated by reference in their entireties.

### BACKGROUND OF THE INVENTION

### Field of the Invention

The present disclosure relates to the field of display technologies, and in particular, to a light-emitting substrate, a backlight module, and a display device.

### Description of Related Art

With the development of light-emitting diode (LED) technology, backlight sources using sub-millimeter or even micron-scale LEDs have been widely used. As a result, not only can the contrast ratio of products utilizing these backlight sources, such as transmissive liquid crystal displays (LCDs), reach the level of organic light-emitting diode (OLED) display products, but also enable the products to retain the technological advantages of liquid crystal displays, thereby improving the display effect of pictures, and providing the user with good visual experience.

### SUMMARY OF THE INVENTION

In an aspect, a light-emitting substrate is provided. The light-emitting substrate includes a first substrate, a reflective layer and support columns. The reflective layer is disposed on the first substrate and provided with a plurality of first openings, where at least for two cross-sections of a plurality of cross-sections, parallel to a plane where the first substrate is located, of a first opening of the plurality of first openings, an area of a cross-section relatively proximate to the first substrate is less than an area of a cross-section relatively away from the first substrate. The support columns are located on a side of the reflective layer away from the first substrate and fixed on the first substrate, where an orthographic projection of a support column of the support column on the first substrate is a first projection, an orthographic projection of a minimum cross-section of the plurality of cross-sections, parallel to the plane where the first substrate is located, of the first opening is a second projection, and the second projection lies within a range of the first projection.

In some embodiments, the minimum cross-section of the plurality of cross-sections, parallel to the plane where the first substrate is located, of the first opening is a cross-section closest to the first substrate in the plurality of cross-sections.

In some embodiments, a maximum dimension of a surface of the support column facing the first substrate is D₁, and a mounting tolerance of the support column is T₁; and a maximum dimension of the minimum cross-section is D₂, and a dimensional tolerance of the minimum cross-section is T₂, where

$${D}_{2} \leq {D}_{1} - 2 \times \sqrt[2]{{T}_{1}^{2} + {T}_{2}^{2}} .$$

In some embodiments, an edge of the surface of the support column facing the first substrate is in a shape of an arc, and a tolerance of the arc is R, where

$${D}_{2} \leq {D}_{1} - 2 \times \sqrt[2]{{T}_{1}^{2} + {T}_{2}^{2}} - 2 R .$$

In some embodiments, a maximum dimension of a surface of the support column facing the first substrate is D₁, and a mounting tolerance of the support column is T₁; and a maximum dimension of a maximum cross-section of the plurality of cross-sections, parallel to the plane where the first substrate is located, of the first opening is D₃, and a dimensional tolerance of the maximum cross-section is T₃, where

$${D}_{3} \geq {D}_{1} - 2 \times \sqrt[2]{{T}_{1}^{2} + {T}_{3}^{2}} .$$

In some embodiments, an edge of the surface of the support column facing the first substrate is in a shape of an arc, and a tolerance of the arc is R, where

$${D}_{3} \geq {D}_{1} + 2 \times \sqrt[2]{{T}_{1}^{2} + {T}_{3}^{2}} + 2 R .$$

In some embodiments, the light-emitting substrate further includes fixing parts, the support column being fixed to the first substrate by a fixing part of the fixing parts.

In some embodiments, a material of the fixing part includes hot melt adhesive.

In some embodiments, the reflective layer includes a first reflective sub-layer and a second reflective sub-layer that are disposed on the first substrate; and the first opening includes a first sub-hole and a second sub-hole communicating with each other, the first sub-hole extending through the first reflective sub-layer and the second sub-hole extending through the second reflective sub-layer; and the first sub-hole is further away from the first substrate compared to the second sub-hole, and a hole diameter of an end of the first sub-hole proximate to the second sub-hole is greater than a hole diameter of an end of the second sub-hole proximate to the first sub-hole, so as to form a stepped structure in a sidewall of the first opening.

In some embodiments, a maximum dimension of a surface of the support column facing the first substrate is greater than a maximum dimension of a cross-section of the second sub-hole parallel to the plane where the first substrate is located, and less than a maximum dimension of a cross-section of the first sub-hole parallel to the plane where the first substrate is located; and a shape of the second sub-hole is substantially a cylinder, a depth of the second sub-hole is H, a bottom area of the second sub-hole is S, and a tolerance of the depth of the second sub-hole is T₄; and a material of the fixing pad includes hot melt adhesive, mass of the hot melt adhesive is M, density of the hot melt adhesive is ρ, and an adhesive amount tolerance of the hot melt adhesive is T₅, where

$$M = S \times ( H - {T}_{4} ) ρ - {T}_{5} .$$

In some embodiments, the support column includes a support body and a support frame, the support frame being located on a side of the support body proximate the first substrate; and the support frame is located within the second sub-hole; and along a direction perpendicular to the plane where the first substrate is located, a thickness of the support frame is substantially equal to a thickness of the second reflective sub-layer.

In some embodiments, 1 a shape of the second sub-hole is substantially a cylinder, a depth of the second sub-hole is H, a bottom area of the second sub-hole is S, and a tolerance of the depth of the second sub-hole is T₄; and a material of the fixing part includes hot melt adhesive, mass of the hot melt adhesive is M, density of the hot melt adhesive is ρ, and an adhesive amount tolerance of the hot melt adhesive is T₅; and volume of the support frame is V, where

$$M = [ S \times ( H - {T}_{4} ) - V ] ρ - {T}_{5} .$$

In some embodiments, the light-emitting substrate further includes at least one alignment mark, at least one of the plurality of first openings being provided therein with an alignment mark of the at least one alignment mark.

In some embodiments, the substrate includes a base and a plurality of conductive layers disposed on the base; and the alignment mark is of a same material and disposed in a conductive layer of the plurality of conductive layers: or the alignment mark includes multiple portions arranged in layers, with each portion being of a same material and disposed in a respective conductive layer of the plurality of conductive layers.

In some embodiments, a reflectivity of the support column is substantially the same as a reflectivity of the reflective layer.

In some embodiments, the reflective layer is further provided with a plurality of second openings; and at least for two cross-sections of a plurality of cross-sections, parallel to the plane where the first substrate is located, of a second opening of the plurality of second openings, an area of a cross-section relatively proximate to the first substrate is less than an area of a cross-section relatively away from the first substrate. The light-emitting substrate further includes light-emitting devices, located on the side of the reflective layer away from the first substrate and fixed on the first substrate, where an orthographic projection of a light-emitting device of the light-emitting devices on the first substrate is a third projection, an orthographic projection of a minimum cross-section of the plurality of cross-sections, parallel to the plane where the first substrate is located, of the second opening is a fourth projection, and the third projection falls into the fourth projection.

In some embodiments, the light-emitting substrate further includes a reflective part, at least partially disposed within the second opening and covering at least a portion of the first substrate that is exposed between the second opening and the light-emitting device.

In some embodiments, a reflectivity of the reflective part is substantially the same as a reflectivity of the reflective layer.

In another aspect, a backlight module is provided. The backlight module includes the light-emitting substrate described in any of the above embodiments and a plurality of optical film sheets. The light-emitting substrate has a light exit side and a non-light exit side opposite to each other; and the plurality of optical film sheets are disposed on the light exit side of the light-emitting substrate.

In yet another aspect, a display device is provided. The display device includes the backlight module described in any of the above embodiments and a display panel.

The display panel is disposed on a side, away from the light-emitting substrate, of the plurality of optical film sheets in the backlight module.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a sectional view of a display device, in accordance with some embodiments;

FIG. 3A is a top view of a light-emitting substrate, in accordance with some embodiments;

FIG. 3B is a top view of a light-emitting substrate, in accordance with some other embodiments;

FIG. 4 is a cross-sectional view of the light-emitting substrate of FIG. 3B taken along Q-Q′;

FIG. 5 is a cross-sectional view of the light-emitting substrate of FIG. 3A taken along Q-Q′;

FIG. 6 is a partially enlarged view of the region N2 in FIG. 5;

FIG. 7 is a partially enlarged view of the region M2 in FIG. 5;

FIG. 8 is a partially enlarged view of the region N1 of the light-emitting substrate of FIG. 4, in accordance with some embodiments;

FIG. 9 is a top view of FIG. 8;

FIG. 10 is a partially enlarged view of the region N1 of the light-emitting substrate of FIG. 4, in accordance with some other embodiments;

FIG. 11 is a top view of FIG. 10;

FIG. 12 is a partially enlarged view of the region N1 of the light-emitting substrate of FIG. 4, in accordance with yet some other embodiments;

FIG. 13 is a top view of FIG. 12;

FIG. 14 is a partially enlarged view of the region M1 of the light-emitting substrate of FIG. 4, in accordance with some embodiments;

FIG. 15 is a top view of FIG. 14;

FIG. 16 is a schematic diagram showing a position of each test point; and

FIG. 17 is a diagram showing the test results of the height uniformity of various support columns.

### DESCRIPTION OF HE INVENTION

The technical solutions in embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/multiple” means two or more unless otherwise specified.

Some embodiments may be described using the terms “coupled”, “connected” and their derivatives. For example, the term “connected” may be used in the description of some embodiments to indicate that two or more components are in direct physical or electrical contact with each other. As another example, the term “connected” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation, or other action that is “based on” one or more of the stated conditions or values may, in practice, be based on additional conditions or value beyond those stated.

The terms “parallel”, “perpendicular” and “equal” as used herein include the stated conditions and the conditions similar to the stated conditions, and the range of the similar conditions is within the acceptable deviation range, where the acceptable deviation range is determined by a person of ordinary skill in the art in consideration of the measurement in question and the error associated with the measurement of a specific quantity (i.e., the limitation of the measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

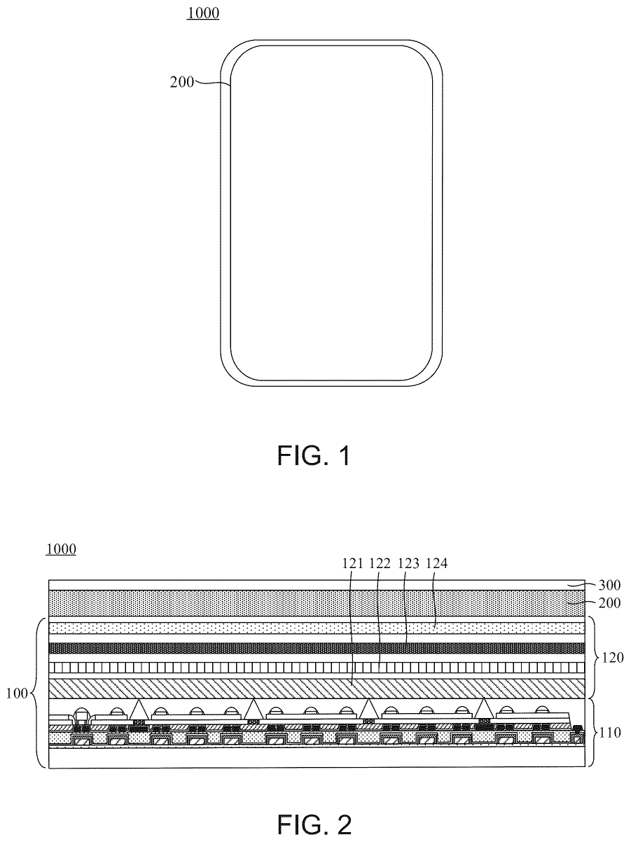

Referring to FIG. 1, some embodiments of the present disclosure provide a display device 1000, and the display device 1000 may be any device that can display an image whether in motion (e.g., video) or stationary (e.g., a still image), and whether textual or pictorial. By way of example, the display device 1000 may be any product or component having a display function, such as a television, a laptop computer, a tablet computer, a cell phone, a personal digital assistant (PDA), a navigator, a wearable device, an augmented reality (AR) device, a virtual reality (VR) device, or the like.

In some embodiments, the display device 1000 may be a liquid crystal display (LCD) device.

Referring to FIG. 2, the display device 1000 may include a backlight module 100, a display panel 200 and a glass cover plate 300. The display panel 200 includes a light exit side and a non-light exit side disposed opposite to each other. The light exit side refers to a side of the display panel 200 for displaying pictures (an upper side of the display panel 200 in FIG. 2), and the non-light exit side refers to the other side opposite to the light exit side. The backlight module 100 is disposed on the non-light exit side of the display panel 200 (a lower side of the display panel 200 in FIG. 2), and the backlight module 100 is used for providing a light source for the display panel 200.

As shown in FIG. 2, the above-described backlight module 100 may include a light-emitting substrate 110 and a plurality of optical film sheets 120. The light-emitting substrate 110 has a light exit side and a non-light exit side disposed opposite to each other, and the plurality of optical film sheets 120 are disposed on the light exit side of the light-emitting substrate 110. In this case, the light-emitting substrate 110 can directly emit white light, and the white light is emitted to the display panel 200 after uniformizing treatment; alternatively, the light-emitting substrate 110 can emit light of another color, which is then emitted to the display panel 200 after color conversion and uniformizing treatment.

By way of example, referring to FIG. 2, the plurality of optical film sheets 120 include a diffusion plate 121, a quantum dot film 122, a diffusion sheet 123, and a composite film 124 which are arranged sequentially along a direction away from the light-emitting substrate 110. Among them, the diffusion plate 121 and the diffusion sheet 123 can uniformize light to alleviate the light shadow produced by the light-emitting substrate 110, improving the display picture quality of the display device 1000. The composite film 124 can improve the light output efficiency of the backlight module 100, improving the display brightness of the display device 1000. The quantum dot film 122 can be excited by light of a certain color emitted from the light-emitting substrate 110 and convert that light into white light to increase the utilization of light energy of the light-emitting substrate 110.

For example, the light-emitting substrate 110 emits blue light, and the quantum dot film 122 may include a red quantum dot material, a green quantum dot material, and a transparent material. A portion of the blue light emitted by the light-emitting substrate 110 is converted to red light when passing through the red quantum dot material; another portion of the blue light is converted to green light when passing through the green quantum dot material; the rest portion of the blue light can pass directly through the transparent material; and then, the blue light, the red light, and the green light are mixed and superimposed in a certain ratio to present as white light.

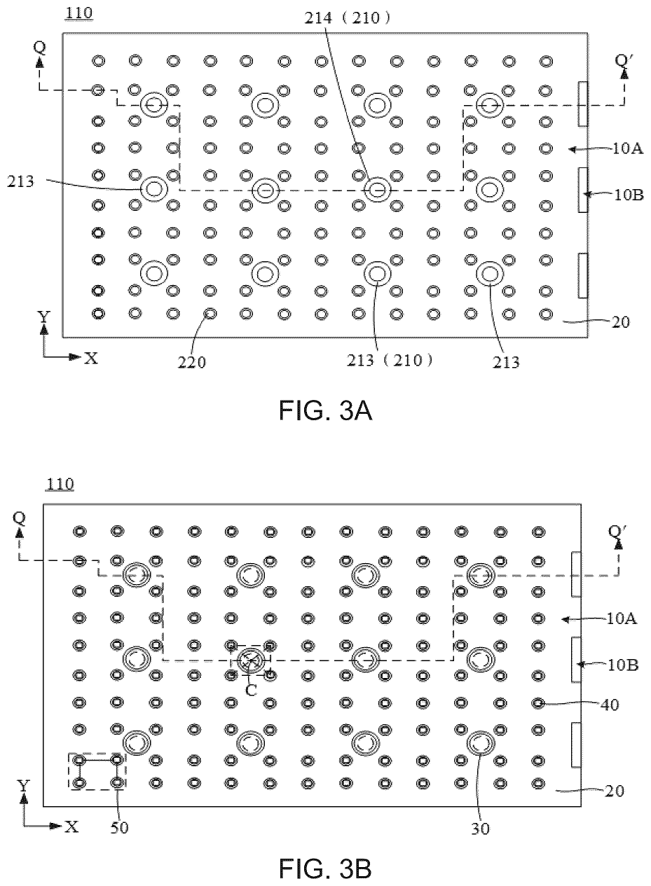

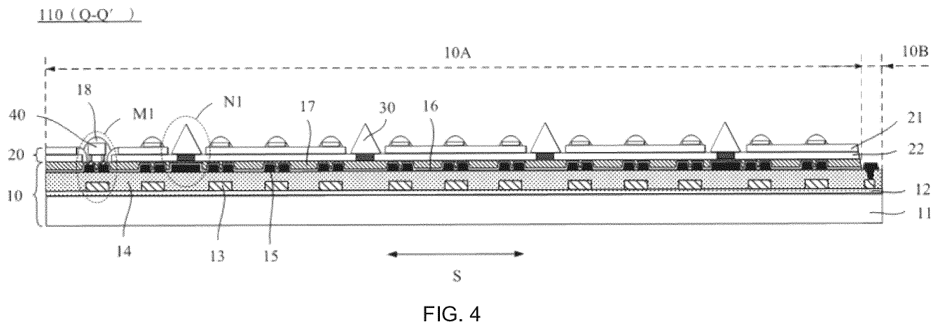

In some embodiments, referring to FIGS. 3B, and 4, the light-emitting substrate 110 includes a first substrate 10, a reflective layer 20, support columns 30, and light-emitting devices 40.

As shown in FIG. 4, the first substrate 10 may include a base 11.

The base 11 includes any one of, for example, a glass base, a quartz base, a sapphire base, a ceramic base, and the like; alternatively, the base 11 includes any one of, for example, a single-crystal semiconductor base or polycrystal semiconductor base with silicon or silicon carbide as the material, a compound semiconductor base (such as silicon-germanium), a silicon-on-insulator (SOI) base; alternatively, the base 11 may include an organic resin material such as epoxy resin, triazine, silicon resin, or polyimide, and in this case, the base 11 is further provided with at least one conductive layer.

By way of example, referring to FIG. 4, the first substrate 10 further includes a buffer layer 12, a second conductive layer 13, an insulating layer 14, a first conductive layer 15, a passivation layer 16, and a passivation layer 17, which are stacked on a side of the base 11 in sequence and along a direction perpendicular to the base 11 and away from the base 11. The first conductive layer 15 may include bonding pads to be connected to light-emitting devices and/or leads connecting different bonding pads. The second conductive layer 13 may include traces for transmitting signals. A material of the first conductive layer 15 includes at least one of copper, molybdenum-niobium (MoNb) alloy, nickel, and indium tin oxide. A material of the second conductive layer 13 includes at least one of copper, molybdenum-niobium (MoNb) alloy, nickel, and indium tin oxide.

In some other examples, the base 11 may be an FR4 (Flame Retardant level 4) type printed circuit board (PCB), or may be a flexible PCB that is easily deformable. In some exemplary embodiments, the base may include a ceramic material such as silicon nitride, AlN, or Al₂O₃, or a metal or metal compound, or a metal core printed circuit board (Metal Core PCB) or a metal copper clad lamination (MCCL) board.

As shown in FIGS. 3B and 4, at least a portion of a boundary of the reflective layer 20 coincides with at least a portion of a boundary of the first substrate 10.

By way of example, as shown in FIGS. 3B and 4, the first substrate 10 includes a light-emitting region 10A and functional regions 10B, where the light-emitting region 10A is configured to be provided with light-emitting devices 40, and microchip (not shown in the figures) therein, and the functional regions 10B are configured to bond a circuit board. The microchips include sensing chips and driving chips, where the sensing chips may be, for example, light-sensitive sensor chips, thermo-sensitive sensor chips, etc., and the driving chips are used to provide driving signals to the light-emitting devices.

The boundary of the reflective layer 20 coincides with a boundary of the light-emitting region 10A of the first substrate 10, that is, the functional regions 10B of the first substrate 10 are not provided with the reflective layer 20. FIGS. 3B and 4 are illustrated with a portion of the boundary of the reflective layer 20 coinciding with a portion of the boundary of the first substrate 10 as an example.

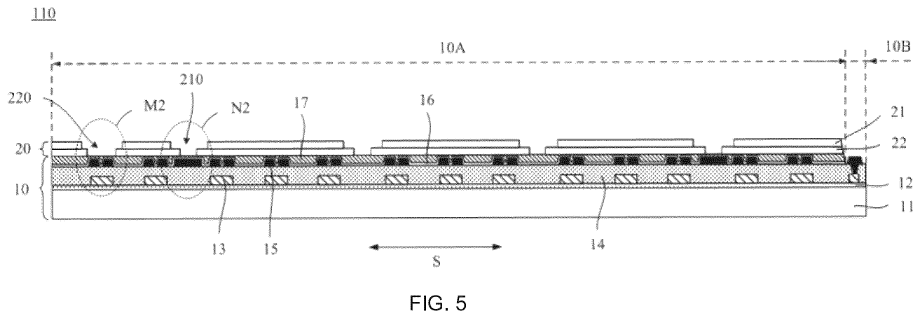

As shown in FIGS. 4 and 5, the reflective layer 20 is provided with a plurality of first openings 210 and a plurality of second openings 220. A support column 30 is fixed to the first substrate 10 through a first opening 210, and a light-emitting device 40 is fixed to the first substrate 10 through a second opening 220.

It will be noted that, a contour of an orthographic projection of the first opening 210 on the first substrate 10 may be in a shape of a circle, a triangle, a rectangle, or the like, and embodiments of the present disclosure are not specifically limited herein; and a contour of an orthographic projection of the second opening 220 on the first substrate 10 may be in a shape of a circle, a triangle, a rectangle, or the like, and embodiments of the present disclosure are not specifically limited herein.

Here, a reflectivity of the reflective layer 20 is greater than or equal to 90%. By way of example, a material of the reflective layer 20 may include a white ink and/or a silicone-based white adhesive. For example, the material of the reflective layer 20 may include a resin (e.g., an epoxy resin, or a polytetrafluoroethylene resin), titanium dioxide (chemical formula TiO₂), and an organic solvent (e.g., dipropylene glycol methyl ether).

Referring to FIGS. 2 and 4, the support columns 30 are used to support the optical film sheets 120 that are on the light exit side of the light-emitting substrate 110, so as to make the reflective layer 20 in the light-emitting substrate 110 and the optical film sheets 120 have a light-mixing distance therebetween, thereby alleviating the light shadow produced by the light-emitting substrate 110 and improving the display picture quality of the display device 1000.

It will be noted that a reflectivity of the above-described support column 30 may be substantially equal to the reflectivity of the reflective layer 20, that is, the reflectivity of the support column 30 is greater than or equal to 90%, so as to make the display brightness of a picture substantially the same at various positions, improving the uniformity of the brightness of the picture. By way of example, a material of the support column 30 may include white high-molecular polymers. For example, the material of the support column 30 may include white polycarbonate.

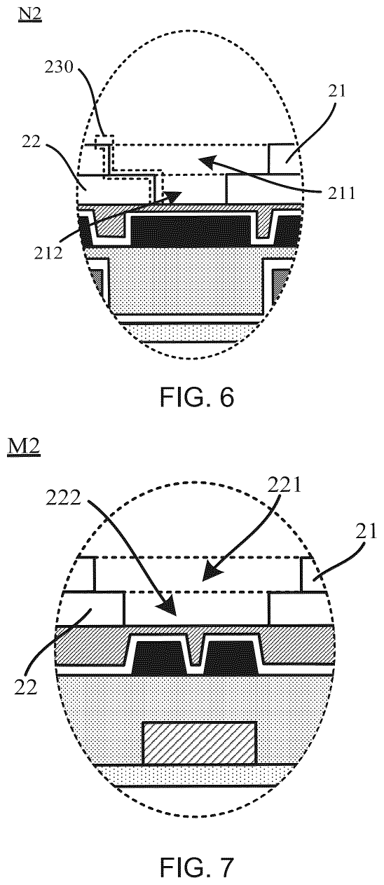

In some embodiments, as shown in FIGS. 5 and 6, at least for two cross-sections of a plurality of cross-sections, parallel to a plane where the first substrate 10 is located, of a first opening 210, an area of a cross-section relatively proximate to the first substrate 10 is less than an area of a cross-section relatively away from the first substrate 10.

It will be noted that “the plane where the first substrate 10 is located” may refer to a surface of the first substrate 10 that has the maximum planar area.

In addition, among the plurality of cross-sections of the first opening 210 parallel to the plane where the first substrate 10 is located, a minimum cross-section is a cross-section closest to the first substrate 10.

By way of example, as shown in FIGS. 5 and 6, a cross-section of the first opening 210 perpendicular to the plane where the first substrate 10 is located is approximately in a shape of an inverted trapezoid.

By way of example, as shown in FIGS. 5 and 6, the first opening 210 includes multiple sub-holes communicating with each other, sidewalls of at least two sub-holes of the plurality of sub-holes are not flush, and an area of a cross-section of the first opening 210 relatively proximate to the first substrate 10 is less than an area of a cross-section of the first opening 210 relatively away from the first substrate 10.

For example, as shown in FIGS. 5 and 6, the reflective layer 20 includes a first reflective sub-layer 21 and a second reflective sub-layer 22 that are disposed on the first substrate 10, where the second reflective sub-layer 22 is in direct contact with the substrate 10, and the first reflective sub-layer 21 is disposed on a side of the second reflective sub-layer 22 away from the first substrate 10. The first opening 210 includes a first sub-hole 211 and a second sub-hole 212 communicating with each other, where the first sub-hole 211 is further away from the substrate 10 compared to the second sub-hole 212, the first sub-hole 211 extends through the first reflective sub-layer 21, and the second sub-hole 212 extends through the second reflective sub-layer 22. A hole diameter of an end of the first sub-hole 211 proximate to the second sub-hole 212 is greater than a hole diameter of an end of the second sub-hole 212 proximate to the first sub-hole 211, so as to form a stepped structure 230 in a sidewall of the first opening 210.

In this case, in a process of forming the first sub-hole 211 and the second sub-hole 212, the second sub-hole 212 can be formed directly after the second reflective sub-layer 22 is formed, and the first sub-hole 211 can be formed directly after the first reflective sub-layer 21 is formed. That is to say, a depth of the first sub-hole 211 is determined by a thickness of the first reflective sub-layer 21, and a depth of the second sub-hole 212 is determined by the thickness of the second reflective sub-layer 22, so as to facilitate control of the depths of the first sub-hole 211 and the second sub-hole 212, with low process difficulty.

It will be noted that, a contour of an orthographic projection of the first sub-hole 211 on the first substrate 10 may be in a shape of a circle, a triangle, a rectangle, or the like, and embodiments of the present disclosure are not specifically limited herein; and a contour of an orthographic projection of the second sub-hole 212 on the last substrate 10 may be in a shape of a circle, a triangle, a rectangle, or the like, and embodiments of the present disclosure are not specifically limited herein.

In addition, the depth of the first sub-hole 211 is in a range of 25 μm to 35 μm, inclusive. For example, the depth of the first sub-hole 211 is any one of 25 μm, 28 μm, 30 μm, 32 μm, and 35 μm. The depth of the second sub-hole 212 is in a range of 25 μm to 35 μm, inclusive. For example, the depth of the second sub-hole 212 is any one of 25 μm, 28 μm, 30 μm, 32 μm, and 35 μm.

On this basis, referring to FIGS. 6, 8 and 9, an orthographic projection of a support column 30 on the fans substrate 10 is a first projection, an orthographic projection of a minimum cross-section of the plurality of cross-sections, parallel to the plane where the first substrate 10 is located, of the first opening 210 is a second projection, and the second projection lies within a range of the first projection. In this way, the minimum cross-section can be shielded by the support column 30, avoiding the problem that a region between a boundary of the first opening 210 of the reflective layer 20 and the support column 30 is unable to reflect light, which results in a reduction of the reflection area, thereby improving the overall light output efficiency of the light-emitting substrate 110, and improving the display effect of the display device 1000.

It will be noted that the second projection lying within the range of the first projection including that a boundary of the second projection substantially coincides with a boundary of the first projection.

By way of example, as shown in FIGS. 6, 8, and 9, in a case where the first opening 210 includes the first sub-hole 211 and the second sub-hole 212 communicating with each other, an orthographic projection (the second projection) of the second sub-hole 212 on the first substrate 10, lies within a range of an orthographic projection (the first projection) of the support column 30 on the first substrate 10.

For example, an area of the first projection is at least 1.16 times an area of the second projection, so as to avoid that the support column 30 is unable to cover the minimum cross-section due to a mounting tolerance of the support column 30 and a dimensional tolerance of the minimum cross-section, which in turn leads to a partial region of the first opening 210 being exposed, and no reflective layer exists in the region of the first opening 210 being exposed, and a loss of light occurs in that position. The area of the first projection is at least 1.16 times the area of the second projection, which may avoid that a partial region of the first opening 210 is exposed, thereby avoiding the occurrence of light loss, improving the overall light output efficiency of the light-emitting substrate 110, and improving the display effect.

By way of example, as shown in FIG. 9, a maximum dimension of a surface of the support column 30 facing the first substrate is D₁, and a mounting tolerance of the support column 30 is T₁; and a maximum dimension of the minimum cross-section is D₂, and a dimensional tolerance of the minimum cross-section is T₂, where

$${D}_{2} \leq {D}_{1} - 2 \times \sqrt[2]{{T}_{1}^{2} + {T}_{2}^{2}} .$$

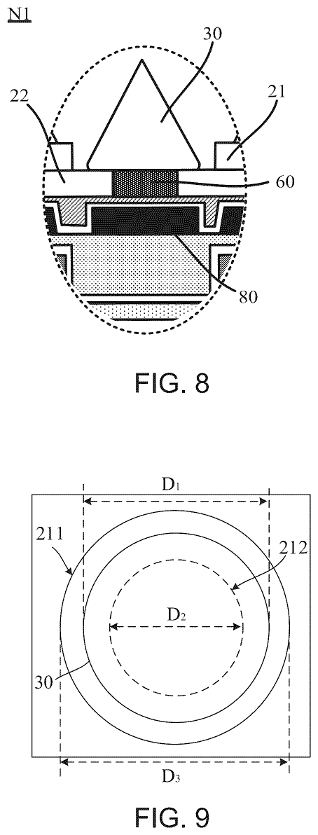

In some embodiments, referring to FIG. 8, an edge of the surface of the support column 30 facing the first substrate 10 is in a shape of an arc, and the maximum dimension of the minimum cross-section of D₂ should satisfy the following formula:

$${D}_{2} \leq {D}_{1} - 2 \times \sqrt[2]{{T}_{1}^{2} + {T}_{2}^{2}} - 2 R .$$

Here, a tolerance of the arc is R, and the tolerance R includes the amount of variation between the actual size and the designed size due to fabrication and/or material surface roughness.

The following is illustrated as an example where the support column 30 is substantially in a shape of a circular cone, and the first opening 210 includes the first sub-hole 211 and the second sub-hole 212 communicating with each other.

As shown in FIGS. 4, 8, and 9, the surface of the support column 30 facing the first substrate 10 is in a shape of a circle, then the maximum dimension D₁ of the support column 30 is a maximum radial dimension of the support column 30; and the plurality of cross-sections, parallel to the plane where the first substrate 10 is located, of the first opening 210 are each in a shape of a circle, then the maximum dimension D₂ of the minimum cross-section of the first opening 210 is a radial dimension of the second sub-hole 212, and the dimensional tolerance T₂ of the minimum cross-section is a radial dimensional tolerance of the second sub-hole 212.

In this case, the radial dimension D₂ of the second sub-hole 212 is set according to the radial dimension D₁ of the support column 30, as well as the mounting tolerance T₁ of the support column 30, and the radial dimensional tolerance T₂ of the second sub-hole 212, so that the support column 30 can block the second sub-hole 212, and the reflective surface area of the reflective layer 20 can be avoided to decrease as a result of the provision of the second sub-hole 212 in the reflective layer 20, thereby avoiding affecting the overall light output efficiency of the light-emitting substrate 110.

By way of example, the maximum radial dimension D₁ of the support column 30 is 5 mm, and the mounting tolerance T₁ of the support column 30 is ±0.02 mg; the radial dimensional tolerance T₂ of the second sub-hole 212 is ±0.3 mm; and the tolerance R of the support column 30 is ±0.04 mm, where

$${D}_{2} \leq 5 - 2 \times \sqrt[2]{{0.02}^{2} + {0.3}^{2}} - 2 \times 0.04 .$$

From the above formula, it can be derived that the radial dimension D₂ of the second sub-hole 212 is substantially less than or equal to 4.2 mm. For example, the radial dimension D₂ of the second sub-hole 212 is substantially equal to 4.2 mm, so as to enable a relatively large bonding area between a fixing part 60 as will be described hereinbelow and the support column 30, and to improve the strength of the bonding between the support column 30 and the fixing part 60.

In addition, an orthographic projection of a maximum cross-section the plurality of cross-sections, parallel to the plane where the first substrate 10 is located, of the first opening 210 is a fifth projection, and the above mentioned first projection (an orthographic projection of the support column 30 on the first substrate 10) lies within a range of the fifth projection, in order to reduce the difference in the brightness of the reflection due to the difference in the reflectivity of different reflective surfaces, as well as to improve the uniformity of the light mixing distance of the reflective layer 20 at various positions.

It will be noted that the first projection lying within the range of the fifth projection including that a boundary of the first projection substantially coincides with a boundary of the fifth projection.

By way of example, as shown in FIGS. 6, 8, and 9, in a case where the first opening 210 includes the first sub-hole 211 and the second sub-hole 212 communicating with each other, the orthographic projection (the first projection) of the support column 30 on the first substrate 10, lies within a range of an orthographic projection (the fifth projection) of the first sub-hole 211 on the first substrate 10.

Moreover, an area of the fifth projection is at least 1.14 times an area of the first projection to avoid that the support column 30 cannot extend into the first opening 210 due to the mounting tolerance of the support column 30 and the dimensional tolerance of the maximum cross-section.

By way of example, referring to FIG. 9, the maximum dimension of the surface of the support column 30 facing the first substrate 10 is D₁, and the mounting tolerance of the support column 30 is T₁; and a maximum dimension of the maximum cross-section is D₃, and a dimensional tolerance of the maximum cross-section is T₃, where

$${D}_{3} \geq {D}_{1} + 2 \times \sqrt[2]{{T}_{1}^{2} + {T}_{3}^{2}} .$$

In some embodiments, referring to FIG. 8, an edge of the surface of the support column 30 facing the first substrate 10 is in a shape of an arc. Considering the dimensional fabrication tolerance and surface roughness of the arc, the maximum dimension of the minimum cross-section of D₂ should satisfy the following formula:

$${D}_{3} \geq {D}_{1} + 2 \times \sqrt[2]{{T}_{1}^{2} + {T}_{3}^{2}} + 2 R .$$

Here, a tolerance of the arc is R, and the tolerance R includes the amount of variation between the actual size and the designed size due to fabrication and/or material surface roughness.

The following is illustrated as an example where the support column 30 is substantially in a shape of a circular cone, and the first opening 210 includes the first sub-hole 211 and the second sub-hole 212 communicating with each other.

In this case, as shown in FIGS. 4, 8, and 9, the surface of the support column 30 facing the first substrate 10 is in a shape of a circle, then the maximum dimension D₁ of the support column 30 is a maximum radial dimension of the support column 30; and the plurality of cross-sections, parallel to the plane where the first substrate 10 is located, of the first opening 210 are each in a shape of a circle, then the maximum dimension D₃ of the maximum cross-section of the first opening 210 is a radial dimension of the first sub-hole 211, and the dimensional tolerance T₃ of the maximum cross-section is a radial dimensional tolerance of the first sub-hole 211.

In this case, the radial dimension D₃ of the first sub-hole 211 is set according to the radial dimension D₁ of the support column 30, as well as the mounting tolerance T₁ of the support column 30 and the radial dimensional tolerance T₃ of the first sub-hole 211, such that the support column 30 extends into the first opening 210. For example, the support column 30 extends into the first opening 210 and is in direct contact with a first surface of the step structure 230, the first surface being a surface of the step structure 230 that is located within the first opening 210 and is substantially parallel to the plane where the first substrate 10 is located. In this way, end surfaces of all the support columns 30 proximate to the first substrate 10 are located in a same reference surface, i.e., a plane where the first surface of the step structure 230 is located. In this way, heights of end portions of all the support columns 30 for supporting the optical film sheets 120 are uniform, and heights of the support columns 30 for supporting respective regions of the optical film sheets 120 are approximately equal, which may improve the flatness of a surface of the optical film sheets 120 and reduce the risk of poor optical uniformity.

By way of example, the maximum radial dimension D₁ of the support column 30 is 5 mm, and the mounting tolerance T₁ of the support column 30 is ±0.02 mg; the radial dimensional tolerance T₃ of the first sub-hole 211 is ±0.3 mm; and the tolerance R of the support column 30 is ±0.04 mm, where

$${D}_{3} \geq 5 + 2 \times \sqrt[2]{{0.02}^{2} + {0.3}^{2}} + 2 \times 0.04 .$$

From the above formula, it can be derived that the radial dimension D₃ of the first sub-hole 211 is substantially greater than or equal to 5.8 mm. For example, the radial dimension D₃ of the first sub-hole 211 is substantially equal to 5.8 mm, so that the radial dimension of the first sub-hole 211 can be minimized as much as possible, so as to reduce a reflection area of the second reflective sub-layer 22, reduce the difference in the brightness of the reflection due to the difference in reflectivity of the first reflective sub-layer 21 and the second reflective sub-layer 22, and increase the uniformity of the mixing distances at various positions of the reflective layer 20.

In some embodiments, as shown in FIGS. 4 and 8, the above-described support column 30 and the first substrate 10 may be connected via a fixing part 60. By way of example, the light-emitting substrate 110 further includes fixing parts 60, and the support column 30 is fixed to the first substrate 10 via a fixing part 60.

It will be noted that a material of the fixing part 60 may include a glue, which forms the fixing part 60 after curing. By way of example, the material of the fixing part 60 may include a hot melt adhesive. For example, the material of the fixing part 60 includes polyurethane resin (PUR), which is characterized by high-temperature resistance and ensures the stability of the fixing part 60 at high temperatures.

In some embodiments, referring to FIGS. 4 and 8, the maximum dimension of the surface of the support column 30 facing the first substrate 10 is greater than a maximum dimension of a cross-section of the second sub-hole 212 parallel to the plane where the first substrate 10 is located and less than a maximum dimension of a cross-section of the first sub-hole 211 parallel to the plane where the first substrate 10 is located.

On this basis, a plurality of cross-sections, parallel to the plane where the first substrate 10 is located, of the second sub-hole 212 are congruent to each other, a depth of the second sub-hole 212 is H, a bottom area of the second sub-hole 212 is S, and a tolerance of the depth of the second sub-hole 212 is T₄; and the mass of the hot melt adhesive is M, the density of the hot melt adhesive is ρ, and an adhesive amount tolerance of the hot melt adhesive is T₅, where

$$M = S \times ( H - {T}_{4} ) ρ - {T}_{5} .$$

It will be noted that in a case where the reflective layer 20 includes the first reflective sub-layer 21 and the second reflective sub-layer 22, and the second sub-hole 212 correspondingly extends through the second reflective sub-layer 22, the depth of the second sub-hole 212 is equal to a thickness of the second reflective sub-layer 22, and the tolerance of the depth of the second sub-hole 212 is equal to a tolerance of the thickness of the second reflective sub-layer 22.

In this case, the adhesive amount of hot melt adhesive is set according to a volume of the second sub-hole 212 and the tolerance of the adhesive amount. This allows the hot melt adhesive with the adhesive amount used to form the fixing part 60 to substantially fill the second sub-hole 212, and avoids overflow of the hot melt adhesive from the second sub-hole 212 while ensuring the reliability of the connection of the hot melt adhesive to the substrate 10 and the support column 30. This in turn prevents the hot melt adhesive from overflowing the second sub-hole 212 from causing the support column 30 to tilt and affecting the flatness of the surface of the optical film sheets 120, and reduces the risk of poor optical uniformity, as well as avoids the problem of color deviation caused by the hot melt adhesive overflowing the edge of the support column 30.

By way of example, the orthographic projection of the above second sub-hole 212 on the first substrate 10 is in a shape of a circle, the plurality of cross-sections, parallel to the plane where the first substrate 10 is located, of the second sub-hole 212 are each other as a congruent circle, and the diameter of the second sub-hole 212 is 4.2 mm; the thickness of the second reflective sub-layer 22 is 0.03 mm, and the tolerance of the thickness of the second reflective sub-layer 22 is ±0.005 mm; and the density p of the hot melt adhesive is 1.1 g/cm³, and the tolerance T₅ of the spray amount of the hot melt adhesive is ±0.02 mg, where

$$M = π ( 4.2 \times 4.2 \div 4 ) \times ( 0.03 - 0.005 ) \times 1.1 \div 1000 - 0.2 .$$

The mass M of the hot melt adhesive can be derived from the above equation to be approximately 0.36 mg.

It will be noted that corresponding formulas are not the same for second sub-holes 212 having different shapes. However, regardless of whether the overall shape of the second sub-hole 212 is in a shape of a cylinder or a prism, as long as the tolerance of the depth of the second sub-hole 212 is taken into account in the corresponding volume formulae.

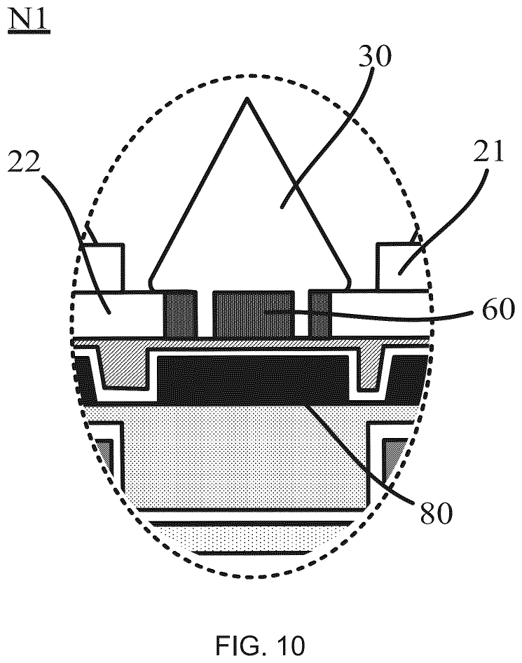

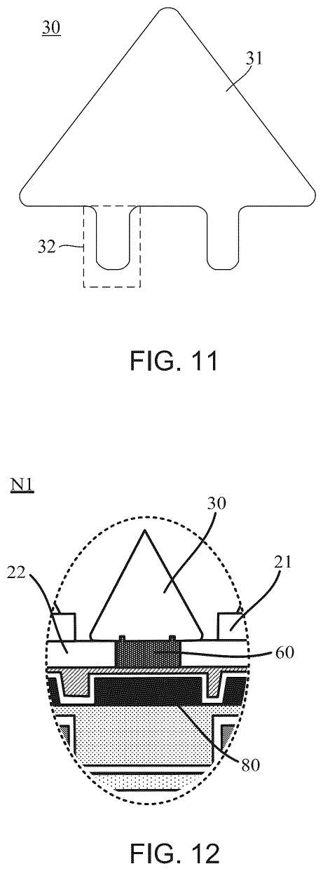

In some other embodiments, referring to FIGS. 4, 10 and 11, the support column 30 includes a support body 31 and a support frame 32, where the support frame 32 is located on a side of the support body 31 proximate to the first substrate 10, and the support frame 32 is located within the second sub-hole 212, which can increase the bonding area between the support column 30 and the fixing part 60, improve the bonding strength, and limit the displacement of the support column 30 along a direction S parallel to the plane where the first substrate 10 is located, so as to facilitate the mounting of the support column 30.

It will be noted that an orthographic projection of the support frame 32 on the first substrate 10 is in a shape of a circle, a ring, or multiple ring sectors spaced apart, and the embodiments of the present disclosure are not specifically limited herein.

Furthermore, referring to FIGS. 4, 10, and 11, along a direction perpendicular to the first substrate 10, a thickness of the support frame 32 is approximately equal to a thickness of the second reflective sub-layer 22 to allow the support frame 32 to be in direct contact with the first substrate 10, while the support column 30 may be in direct contact with the step structure 230 (refer to FIG. 6) to ensure uniformity of the mounting heights of the support columns 30.

On this basis, orthographic projections of the plurality of cross-sections, parallel to the plane where the first substrate 10 is located, of the second sub-hole 212 on the first substrate 10 are completely coincident or substantially coincident, the depth of the second sub-hole 212 is H, the bottom area of the second sub-hole 212 is S, and the tolerance of the depth of the second sub-hole 212 is T₄; the mass of the hot melt adhesive is M, the density of the hot melt adhesive is ρ, and the adhesive amount tolerance of the hot melt adhesive is T₅; and the volume of the support frame 32 is V, where

$$M = [ S \times ( H - {T}_{4} ) - V ] ρ - {T}_{5} .$$

It will be noted that in a case where the reflective layer 20 includes the first reflective sub-layer 21 and the second reflective sub-layer 22, and the second sub-hole 212 correspondingly extends through the second reflective sub-layer 22, the depth of the second sub-hole 212 is equal to a thickness of the second reflective sub-layer 22, and the tolerance of the depth of the second sub-hole 212 is equal to a tolerance of the thickness of the second reflective sub-layer 22.

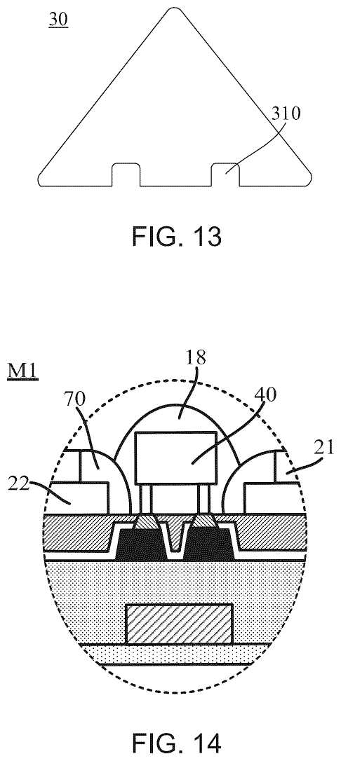

In yet some other embodiments, referring to FIGS. 4, 12 and 13, a surface of the support column 30 proximate to the first substrate 10 is provided with at least one groove 310, and a portion of the fixing part 60 is located within the groove 310 of the support column 30, so as to increase the bonding area between the support column 30 and the fixing part 60, increasing the strength of the bonding between the support column 30 and the fixing part 60, as well as to further reduce the risk of the hot melt adhesive overflowing over the edge of the support column 30.

It will be noted that an orthographic projection of the groove 310 on the first substrate 10 is in a shape of a circle, a ring, or multiple ring sectors spaced apart, and the embodiments of the present disclosure are not specifically limited herein.

In some embodiments, referring to FIGS. 2 and 3B, the support columns 30 may be arranged in multiple rows and multiple columns, with each row including multiple support columns 30 arranged along a first direction X and each column including multiple support columns 30 arranged along a second direction Y. In this way, a relatively uniform support force is provided to the optical film sheets 120, reducing the difference in the amount of deformation in different regions of the optical film sheets 120 supported by the support columns 30, further improving the surface flatness of the optical film sheets 120, and improving the uniformity of a display image. That is, the plurality of first openings 210 may be arranged in multiple rows and multiple columns, with each row including multiple first openings 210 arranged along the first direction X and each column including multiple first openings 210 arranged along the second direction Y.

In addition, a support column 30 has a plurality of cross-sections along the direction S parallel to the plane where the first substrate 10 is located; and areas of the plurality of cross-sections decrease gradually along a thickness direction of the first substrate 10 and from the first substrate 10 to the reflective layer 20. For example, the support column 30 is in a shape of a cone. With the setting in the above manner, the volume of the support column 30 may be reduced, thereby reducing the blocking effect of the support column 30 on light, and improving the light output efficiency of the light-emitting substrate 110.

It will be noted that the support column 30 may be in other shapes, such as a circular truncated cone or a cylinder, and embodiments of the present disclosure are not specifically limited herein.

In some embodiments, referring to FIG. 3B, the plurality of light-emitting devices 40 may be arranged in multiple rows and columns, with each row including multiple light-emitting devices 40 arranged along the first direction X and each column including multiple light-emitting devices 40 arranged along the second direction Y.

Here, as shown in FIG. 3B, the support column 30 may be located at a center C of a region surrounded by lines connecting centers of four light-emitting devices 40 that are immediately adjacent to one another, so that a distance between the support column 30 and each of the four light-emitting devices 40 is approximately equal, so as to avoid that the support column 30 is too close to any one of the four light-emitting devices 40, which causes a blockage of light emission of this light-emitting device 40, thereby avoiding to lead to the light-emitting substrate 110 from emitting light unevenly.

In addition, the light-emitting substrate 110 may include a plurality of light-emitting units 50, and the light-emitting units 50 each include multiple light-emitting devices 40 connected in series and/or in parallel.

By way of example, as shown in FIG. 3B, each light-emitting unit 50 includes 4 light-emitting devices 40 sequentially connected in series. Of course, each light-emitting unit 50 may also include 2, 3, 5, or 6 light-emitting devices 40. Moreover, the connection of the multiple light-emitting devices 40 in each light-emitting unit 50 is not limited to a series connection, but may also be a parallel connection or a combination of a series and parallel connection, and the present disclosure embodiments are not limited thereto.

It will be noted that the above light-emitting device 40 may include a micro light-emitting diode (Micro LED) or a sub-millimeter light-emitting diode (Mini LED). Here, a dimension (e.g., length) of the Micro LED is less than 50 micrometers, e.g., in a range of 10 micrometers to 50 micrometers; and a dimension (e.g., length) of the Mini LED is in a range of 50 micrometers to 150 micrometers, inclusive, e.g., in a range of 80 micrometers to 120 micrometers, inclusive.

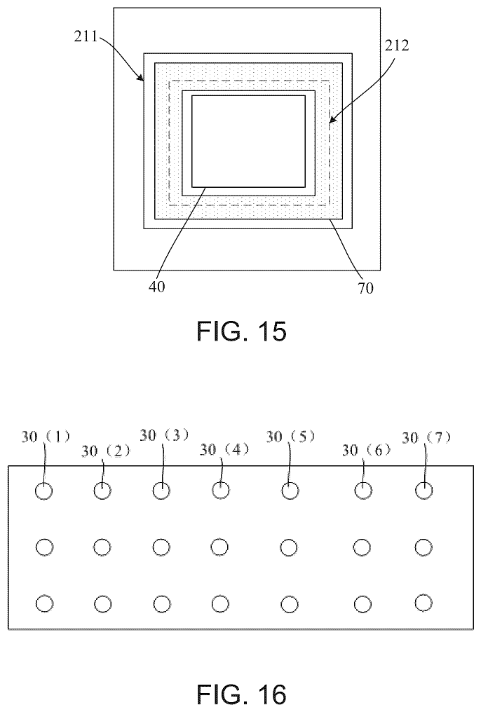

In some embodiments, referring to FIGS. 5, 7 and 15, at least for two cross-sections of a plurality of cross-sections, parallel to the plane where the first substrate 10 is located, of a second opening 220, an area of a cross-section relatively proximate to the first substrate 10 is less than an area of a cross-section relatively away from the first substrate 10.

By way of example, as shown in FIGS. 5, 7, and 15, the above-described reflective layer 20 includes a first reflective sub-layer 21 and a second reflective sub-layer 22 disposed on the first substrate 10, where the second reflective sub-layer 22 is in direct contact with the first substrate 10, and the first reflective sub-layer 21 is located on a side of the second reflective sub-layer 22 away from the first substrate 10. The second opening 220 includes a third sub-hole 221 and a fourth sub-hole 222 communicating with each other, where the third sub-hole 221 is further away from the first substrate 10 compared to the fourth sub-hole 222, the third sub-hole 221 extends through the first reflective sub-layer 21, and the fourth sub-hole 222 extends through the second reflective sub-layer 22. A hole diameter of an end of the third sub-hole 221 proximate to the fourth sub-hole 222 is greater than a hole diameter of an end of the fourth sub-hole 222 proximate to the third sub-hole 221.

It will be noted that, a contour of an orthographic projection of the third sub-hole 221 on the first substrate 10 may be in a shape of a circle, a triangle, a rectangle, or the like, and embodiments of the present disclosure are not specifically limited herein; and a contour of an orthographic projection of the fourth sub-hole 222 on the first substrate 10 may be in a shape of a circle, a triangle, a rectangle, or the like, and embodiments of the present disclosure are not specifically limited herein.

In addition, a depth of the third sub-hole 221 is in a range of 25 μm to 35 μm, inclusive. For example, the depth of the third sub-hole 221 is any one of 25 μm, 28 μm, 30 μm, 32 μm, and 35 μm. A depth of the fourth sub-hole 222 is in a range of 25 μm to 35 μm, inclusive. For example, the depth of the fourth sub-hole 222 is any one of 25 μm, 28 μm, 30 μm, 32 μm, and 35 μm.

On this basis, referring to FIGS. 5, 7, and 15, an orthographic projection of a light-emitting device 40 on the first substrate 10 is a third projection, and an orthographic projection of a minimum cross-section of the plurality of cross-sections, parallel to the plane where the first substrate 10 is located, of the second opening 220 is a fourth projection. The third projection falls into the fourth projection, i.e., a boundary of the third projection lies within a boundary of the fourth projection.

In a case where the second opening 220 includes the third sub-hole 221 and the fourth sub-hole 222 communicating with each other, the boundary of the orthographic projection of the light-emitting device 40 on the first substrate 10 lies within a boundary of an orthographic projection of the fourth sub-hole 222 on the first substrate 10.

In this case, a distance between the light-emitting device 40 and a portion of the reflective layer 20 away from the first substrate 10 is relatively large, i.e., a spacing between the light-emitting device 40 and the first reflective sub-layer 21 is relatively large, so that in a process of fixing the light-emitting device 40 to the first substrate 10, the risk of mutual interference between the light-emitting device 40 and the reflective layer 20 can be reduced, and the difficulty of mounting the light-emitting device 40 can be reduced.

On this basis, as shown in FIGS. 4, 5 and 14, the light-emitting substrate 110 further includes reflective part(s) 70. A reflective part 70 is at least partially disposed within a second opening 220 and covers at least a portion of the first substrate 10 that is exposed between this second opening 220 and a light-emitting device 40 corresponding thereto, so as to increase a reflective area and improve the overall light output efficiency of the light-emitting substrate 110.

By way of example, as shown in FIGS. 4, 14, and 15, an orthographic projection of the reflective part 70 on the first substrate 10 is substantially in a shape of an annulus, in which an inner boundary of the annulus is located between a boundary of an orthographic projection of a fourth sub-hole 222 on the first substrate 10 and a boundary of an orthographic projection of the light-emitting device 40 on the first substrate 10, and an outer boundary of the annulus is located between a boundary of an orthographic projection of a third sub-hole 221 on the Last substrate 10 and the boundary of the orthographic projection of the fourth sub-hole 222 on the first substrate 10.

It will be noted that a reflectivity of the reflective part 70 is substantially the same as a reflectivity of the reflective layer 20. By way of example, the reflectivity of the reflective part 70 is greater than or equal to 90%. For example, a material of the reflective part 70 includes a silicone-based white adhesive.

In some embodiments, as shown in FIGS. 4 and 14, the light-emitting substrate 110 further includes encapsulation parts 18 disposed on a side, away from the first substrate 10, of the light-emitting devices 40 and the microchips, with each encapsulation part 18 enclosing at least one light-emitting device 40 and/or at least one microchip. An encapsulation part 18 enclosing the light-emitting device 40 is made of a transparent material, which may specifically be a transparent silicone; while an encapsulation part enclosing the microchip may be made of a transparent material or a reflective material, where the transparent material may adopt a transparent silicone, and the reflective material may be the same as or similar to the material of the reflective layer 20.

As shown in FIGS. 4, 5, and 8, the light-emitting substrate 110 further includes at least one alignment mark 80, and at least one first opening 210 is provided therein with an alignment mark 80.

By way of example, referring to FIGS. 3A, 5, and 6, the reflective layer 20 is provided with a plurality of first openings 210. The plurality of first openings 210 include edge openings 213 and center openings 214, with the edge openings 213 surrounding the center openings 214. At least one of the edge openings 213 is provided therein with an alignment marking 80.

For example, as shown in FIGS. 3A and 5, a contour of an orthographic projection of the reflective layer 20 on the first substrate 10 is substantially in a shape of a quadrangle having four corners. The plurality of first openings 210 are arranged in multiple rows and multiple columns. Each corner of the above quadrangle is provided with a corresponding edge opening 213, and the four edge openings 213 corresponding to the four corners are each provided therein with an alignment mark 80. In this way, the alignment marks 80 are disposed at the edges of the first substrate 10 to facilitate the acquisition of images of the alignment marks 80 for alignment.

It can be understood that an alignment mark 80 described above can be disposed at any position within a first opening 210. For example, the alignment mark 80 may be disposed at a center of the first opening 210 or at a position other than the center within the first opening 210, ensuring that the first opening 210 exposes the alignment mark 80 to facilitate the acquisition of an image of the alignment mark 80 for alignment.

As can be seen above, the first substrate 10 may include the base 11 and the plurality of conductive layers disposed on the base 11. In this case, an alignment mark 80 is of a same material and disposed in a same layer as structures in a conductive layer of the plurality of conductive layers: alternatively, an alignment mark 80 includes multiple portions arranged in layers, with each portion being of a same material and disposed in a same layer as structures in a respective conductive layer of the plurality of conductive layers.

The term “same layer” refers to a layer structure that is formed by forming a film layer for forming a specific pattern by a same film-forming process, and then patterning the film layer through a single patterning process by utilizing a same mask. Depending on different specific patterns, the signal patterning process may include multiple exposure, development or etching processes, and the specific patterns in the formed layer structure may be continuous or discontinuous, and these specific patterns may also be at different heights or have different thicknesses.

By way of example, referring to FIG. 4, the first substrate 10 further includes a second conductive layer 13, an insulating layer 14, a first conductive layer 15, a passivation layer 16, and a passivation layer 17, which are stacked on a side of the base 11 in a sequence, along a direction perpendicular to the base 11 and away from the base 11. The alignment mark 80 may be formed by either the first conductive layer 15 or the second conductive layer 13, or may be formed by the first conductive layer 15 and the second conductive layer 13 together. For example, the alignment mark 80 may be formed by the first conductive layer 15 to reduce a distance between the alignment mark 80 and a surface of the reflective layer 20 away from the first substrate 10, so that an image of the alignment mark 80 captured from the upper side of the first substrate 10 is clearer, which contributes to the improvement of the alignment accuracy.

In order to objectively evaluate the technical effect of the embodiments of the present disclosure, the light-emitting substrate provided by the above embodiments is subjected to a pushing force test hereinafter, with the test results shown in Table 1.

TABLE 1
Table for a pushing force test on support columns

| Test | Related technology | Related technology | The present |
|---|---|---|---|
| point | 1 | 2 | disclosure |
| 1 | 33 | 35 | 28 |
| 2 | 27 | 28 | 29 |
| 3 | 29 | 29 | 39 |
| 4 | 30 | 30 | 33 |
| 5 | 30 | 36 | 36 |
| 6 | 31 | 35 | 28 |
| 7 | 29 | 27 | 27 |
| 8 | 37 | 30 | 31 |
| 9 | 33 | 32 | 30 |
| MAX | 37 | 36 | 39 |
| MIN | 27 | 27 | 27 |
| AVE | 31 | 31.3 | 31.2 |
| Spec | 20 | 20 | 20 |

Here, related technology 1 represents support columns bonded and fixed with the reflective layer in the related art, related technology 2 represents support columns bonded and fixed with the first substrate in the related art, MAX represents the maximum value of the 9 test points, MIN represents the minimum value of the 9 test points, AVE represents the average value of the 9 test points, and Spec represents the maximum push force that a single support column is required to withstand.

It can be seen from Table 1 that the push force result test at each point of the embodiment of the present disclosure is greater than 20 Newtons (20N), which meets the maximum push force requirement that a single support column is required to withstand. Moreover, the push force test results at all points of the embodiments of the present disclosure are approximately the same as the push force test results of the related art and have not decreased.

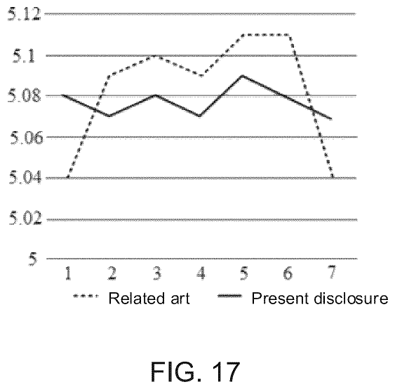

In order to objectively evaluate the technical effect of the embodiments of the present disclosure, the light-emitting substrate provided by the above embodiments is tested for high uniformity hereinafter, with the test results shown in FIGS. 16 and 17, in which FIG. 16 is a schematic diagram showing a position of each test point, and FIG. 17 is a diagram showing the test results of the height uniformity of various support columns.

As shown in FIGS. 16 and 17, the heights of the test points 1 and 7 in the related art are obviously small, and there is no abrupt decrease in the heights of the test points 1 and 7 in the present disclosure; and in this case, the fluctuation of all the test points is small, indicating that the height uniformity of the support columns is better.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting substrate, comprising:
a first substrate;
a reflective layer, disposed on the first substrate and provided with a plurality of first openings, wherein at least for two cross-sections of a plurality of cross-sections, parallel to a plane where the first substrate is located, of a first opening of the plurality of first openings, an area of a cross-section relatively proximate to the first substrate is less than an area of a cross-section relatively away from the first substrate; and
support columns, located on a side of the reflective layer away from the first substrate and fixed on the first substrate, wherein an orthographic projection of a support column of the support columns on the first substrate is a first projection, an orthographic projection of a minimum cross-section of the plurality of cross-sections, parallel to the plane where the first substrate is located, of the first opening is a second projection, and the second projection lies within a range of the first projection.

2. The light-emitting substrate according to claim 1, wherein the minimum cross-section of the plurality of cross-sections, parallel to the plane where the first substrate is located, of the first opening is a cross-section closest to the first substrate in the plurality of cross-sections.

3. The light-emitting substrate according to claim 2, wherein a maximum dimension of a surface of the support column facing the first substrate is D₁, and a mounting tolerance of the support column is T₁; and a maximum dimension of the minimum cross-section is D₂, and a dimensional tolerance of the minimum cross-section is T₂, wherein
$${D}_{2} \leq {D}_{1} - 2 \times \sqrt[2]{{T}_{1}^{2} + {T}_{2}^{2}} .$$

4. The light-emitting substrate according to claim 3, wherein an edge of the surface of the support column facing the first substrate is in a shape of an arc, and a tolerance of the arc is R, wherein
$${D}_{2} \leq {D}_{1} - 2 \times \sqrt[2]{{T}_{1}^{2} + {T}_{2}^{2}} - 2 R .$$

5. The light-emitting substrate according to claim 1, wherein a maximum dimension of a surface of the support column facing the first substrate is D₁, and a mounting tolerance of the support column is T₁; and a maximum dimension of a maximum cross-section of the plurality of cross-sections, parallel to the plane where the first substrate is located, of the first opening is D₃, and a dimensional tolerance of the maximum cross-section is T₃, wherein
$${D}_{3} \geq {D}_{1} + 2 \times \sqrt[2]{{T}_{1}^{2} + {T}_{3}^{2}} .$$

6. The light-emitting substrate according to claim 5, wherein an edge of the surface of the support column facing the first substrate is in a shape of an arc, and a tolerance of the arc is R, wherein
$${D}_{3} \geq {D}_{1} + 2 \times \sqrt[2]{{T}_{1}^{2} + {T}_{3}^{2}} + 2 R .$$

7. The light-emitting substrate according to claim 1, further comprising:
fixing parts, the support column being fixed to the first substrate by a fixing part of the fixing parts.

8. The light-emitting substrate according to claim 7, wherein a material of the fixing part includes hot melt adhesive.

9. The light-emitting substrate according to claim 7, wherein the reflective layer includes a first reflective sub-layer and a second reflective sub-layer that are disposed on the first substrate; and the first opening includes a first sub-hole and a second sub-hole communicating with each other, the first sub-hole extending through the first reflective sub-layer and the second sub-hole extending through the second reflective sub-layer; and
the first sub-hole is further away from the first substrate compared to the second sub-hole, and a hole diameter of an end of the first sub-hole proximate to the second sub-hole is greater than a hole diameter of an end of the second sub-hole proximate to the first sub-hole, so as to form a stepped structure in a sidewall of the first opening.

10. The light-emitting substrate according to claim 9, wherein a maximum dimension of a surface of the support column facing the first substrate is greater than a maximum dimension of a cross section of the second sub-hole parallel to the place where the first substrate is located, and less than a maximum dimension of a cross-section of the first sub-hole parallel to the plane where the first substrate is located; and
a shape of the second sub-hole is substantially a cylinder, a depth of the second sub-hole is H, a bottom area of the second sub-hole is S, and a tolerance of the depth of the second sub-hole is T₄; and a material of the fixing part includes hot melt adhesive, mass of the hot melt adhesive is M, density of the hot melt adhesive is ρ, and an adhesive amount tolerance of the hot melt adhesive is T₅, wherein
$$M = S \times ( H - {T}_{4} ) ρ - {T}_{5} .$$

11. The light-emitting substrate according to claim 9, wherein the support column includes a support body and a support frame, the support frame being located on a side of the support body proximate the first substrate; and
the support frame is located within the second sub-hole; and along a direction perpendicular to the plane where the first substrate is located, a thickness of the support frame is substantially equal to a thickness of the second reflective sub-layer.

12. The light-emitting substrate according to claim 11, wherein a shape of the second sub-hole is substantially a cylinder, a depth of the second sub-hole is H, a bottom area of the second sub-hole is S, and a tolerance of the depth of the second sub-hole is T₄; and a material of the fixing part includes hot mely adhesive, mass of the hot melt adhesive is M, density of the hot melt adhesive is ρ, and an adhesive amount tolerance of the hot melt adhesive is T₅; and volume of the support frame is V, wherein
$$M = [ S \times ( H - {T}_{4} ) - V ] ρ - {T}_{5} .$$

13. The light-emitting substrate according to claim 1, further comprising:
at least one alignment mark, at least one of the plurality of first openings being provided therein with an alignment mark of the at least one alignment mark.

14. The light-emitting substrate according to claim 13, wherein the first substrate includes a base and a plurality of conductive layers disposed on the base; and
the alignment mark is of a same material and disposed in a conductive layer of the plurality of conductive layers; or the alignment mark includes multiple portions arranged in layers, with each portion being of a same material and disposed in a respective conductive layer of the plurality of conductive layers.

15. The light-emitting substrate according to claim 1, wherein a reflectivity of the support column is substantially the same as a reflectivity of the reflective layer.

16. The light-emitting substrate according to claim 1, wherein the reflective layer is further provided with a plurality of second openings; and at least for two cross-sections of a plurality of cross-sections, parallel to the plane where the first substrate is located, of a second opening of the plurality of second openings, an area of a cross-section relatively proximate to the first substrate is less than an area of a cross-section relatively away from the first substrate;
the light-emitting substrate further comprises:
light-emitting devices, located on the side of the reflective layer away from the first substrate and fixed on the first substrate, wherein an orthographic projection of a light-emitting device of the light-emitting devices on the first substrate is a third projection, an orthographic projection of a minimum cross-section of the plurality of cross-sections, parallel to the plane where the first substrate is located, of the second opening is a fourth projection, and the third projection falls into the fourth projection.

17. The light-emitting substrate according to claim 16, further comprising:
a reflective part, at least partially disposed within the second opening and covering at least a portion of the first substrate that is exposed between the second opening and the light-emitting device.

18. The light-emitting substrate according to claim 17, wherein a reflectivity of the reflective part is substantially the same as a reflectivity of the reflective layer.

19. A backlight module, comprising:
the light-emitting substrate as claimed in claim 1, the light-emitting substrate having a light exit side and a non-light exit side opposite to each other; and
a plurality of optical film sheets, disposed on the light exit side of the light-emitting substrate.

20. A display device, comprising:
the backlight module as claimed in claim 19; and
a display panel, disposed on a side, away from the light-emitting substrate, of the plurality of optical film sheets in the backlight module.
